(19) United States
(12) Patent Application Publication
(10) Pub. No.: US 2014/0162473 A1
(43) Pub. Date: Jun. 12, 2014

(54) MOBILE INDEPENDENT LOADING MECHANISM

(71) Applicants: Russell S. Aoki, Tacoma, WA (US); Anthony P. Valpiani, Olympia, WA (US)

(72) Inventors: Russell S. Aoki, Tacoma, WA (US); Anthony P. Valpiani, Olympia, WA (US)

(21) Appl. No.: 13/711,345

(22) Filed: Dec. 11, 2012

(51) Int. Cl. H01R 12/16; H05K 3/30

(52) U.S. Cl. CPC H01R 23/72; H05K 3/30
USPC 439/68; 29/832

(57) ABSTRACT

A mobile device assembly comprising a land grid array (LGA) socket configured to couple with a board of a mobile device. The LGA socket may be configured to couple with a component of the mobile device. A mobile independent loading mechanism (ILM) may at least partially overlap the component and couple with the board of the mobile device via one or more fasteners. By coupling with the board of the mobile device, the mobile ILM may therefore apply pressure to the component, securely holding the component to the LGA socket.

### FIELD

Embodiments of the present disclosure generally relate to the field of mobile device components, and more particularly, to methods and apparatuses for securing a component such as a central processing unit (CPU) to a motherboard in a mobile device.

### BACKGROUND

Pin grid arrays (PGAs) comprising a plurality of pins extending from a component of an integrated circuit have traditionally been used in mobile devices. In general, the pins from the component are matched with a socket that is attached to a board of the mobile device. However, PGAs can have drawbacks in mobile devices. Specifically, PGAs may be susceptible to damage or malfunction from misuse or errors during component installation. Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

### BRIEF DESCRIPTION OF THE DRAWINGS

FIG. 1 illustrates a land grid array (LGA) socket in accordance with embodiments.

FIG. 2 illustrates one embodiment of an assembly utilizing an LGA socket.

FIG. 3 illustrates an exploded view of an assembly utilizing an LGA socket.

FIG. 4 depicts one embodiment of an assembly utilizing an LGA socket and a mobile independent loading mechanism (ILM), in accordance with embodiments.

FIG. 5 depicts another embodiment of an assembly utilizing an LGA socket and a mobile ILM, in accordance with embodiments.

FIG. 6 depicts an exploded view of an assembly utilizing an LGA socket and a mobile ILM, in accordance with embodiments.

FIG. 7 illustrates a flowchart for utilizing an assembly, in accordance with embodiments.

FIG. 8 schematically illustrates a computing device in accordance with one implementation of the invention.

### DETAILED DESCRIPTION

Embodiments of the present disclosure describe an assembly in a mobile device. In embodiments, the assembly may include an LGA socket configured to couple with a component of the mobile device. In some embodiments the component may be a CPU, a semiconductor die, or some other component. The assembly may further include a mobile ILM configured to at least partially overlap the component and provide pressure to the component, thereby holding the component securely within the LGA socket. One or more fasteners may couple the mobile ILM with a printed circuit board (PCB) of the mobile device. For example, the fasteners may couple directly with the PCB, or alternatively they may couple with a backing plate that is on the opposite side of the PCB from the assembly. In some embodiments, the mobile ILM may further couple with a thermal mounting configured to receive one or more thermal components of the mobile device.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical and/or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

As noted above, PGA sockets have been used in mobile devices due to certain desirable properties of the PGA sockets. For example, the PGA sockets may have a smaller volume than alternative sockets such as LGA sockets. However, assemblies utilizing PGA sockets may be undesirable in mobile devices for a plurality of reasons. For example the PGA sockets generally have a corresponding PGA package designed to couple with the PGA socket. The PGA package may require gold-plated pins on the package, which can increase the cost of the PGA package and the corresponding device using the PGA package. Additionally, PGA packages may be susceptible to damage due to misuse or mishandling of the socket or component during manufacture or use of the device incorporating the PGA socket.

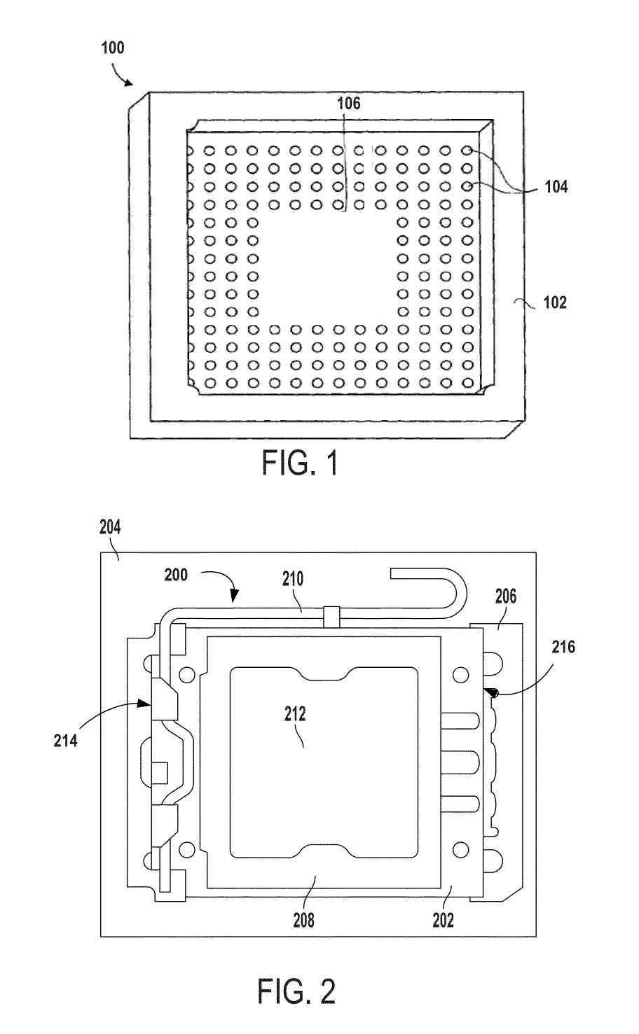

As noted above, alternatives to PGA sockets include BGA sockets and LGA sockets. One embodiment of an LGA socket is depicted in FIG. 1. Specifically, the LGA socket 100 may comprise a socket body 102 with a plurality of contacts 104. In certain embodiments, the contacts 104 may be formed out of conductive metals such as copper or some other conductive material. The contacts 104 of the LGA socket 100 may couple directly with the underside of a component of a mobile device. The contacts 104 may be flat conductive elements, conductive pins, or some other form of contact. In some embodiments, the contacts 104 may be cantilever beams that are configured to interface directly with corresponding flat contacts on the underside of the component of the mobile device. For example, if the contacts are cantilever beams, then the contacts 104 may be compressed against matching flat contacts disposed on the underside of the component. Other configurations of the contacts 104 and corresponding component may be used in other embodiments. The LGA socket 100 may have several advantages. For example, the contacts 104 may be elements of the motherboard rather than the component, and so if a contact 104 is damaged it may be easier or cheaper to repair or replace.

In certain embodiments, the LGA socket 100 may include a space that is substantially contact free, such as center 106. In some embodiments, the center 106 may include additional components or elements. For example, the center 106 may include additional contacts 104. In other embodiments, the center may be cut out of the LGA socket 100 such that the center 106 is a recessed portion of the LGA socket 100. It will be understood that this embodiment of the arrangement of the contacts 104 is merely an example, and other embodiments are possible. For example, although only two rows of contacts 104 are shown in FIG. 1, other embodiments of the LGA socket 100 may include more or less contacts 104.

Because the contacts 104 of the LGA socket 100 may couple directly with a component, force may be required to hold the component tightly against the LGA socket 100. In some embodiments, the LGA socket 100 may require as much as 80 pounds of force to properly couple with a component. To accomplish this amount of force, an assembly 200 utilizing an LGA socket may be used, for example LGA socket 100 as shown in FIG. 2. In some embodiments the assembly 200 may be referred to as an ILM assembly.

The assembly 200 may comprise a frame 202 mounted to a printed circuit board (PCB) 204 of a device. The PCB 204 may be a motherboard of a device or some other circuit board. In some embodiments the frame 202 may be soldered to the PCB 204, though in other embodiments the frame 202 may be glued to the PCB 204 or attached in some other suitable way. The LGA socket 100 may be coupled with the frame 202 or coupled directly with the PCB 204. For example the LGA socket 100 may be glued, soldered, or otherwise connected to the PCB 204. In some embodiments an insulator 206 may be positioned between the frame 202 and the PCB 204. The insulator 206 may act to prevent the frame 202, which may be made of metal, from contacting the PCB 204.

The assembly 200 may further comprise a load plate 208 coupled with the frame 202. In some embodiments, the load plate 208 may be directly coupled with and at least partially under the frame 202. The frame 202 may further include a load lever 210. In embodiments, the load lever 210 may be coupled with the frame 202 at a first side 214 via a hinge.

In certain embodiments, the frame 202 and load plate 208 may rotate via the hinge on the second side 216. In some assemblies, the frame 202 and load plate 208 may be able to rotate separately from one another, while in other embodiments they may be affixed to one another. A circuit component (not shown) with contacts, for example a computer processing unit, a semiconductor die, or some other component, may be placed within the frame 202 such that the contacts of the component are directly coupled with the contacts 104 of the LGA socket 100. In some embodiments, the component may be coupled directly with an integrated heat spreader (IHS) 212. In other embodiments the IHS 212 may be separate from, but placed over, the component.

After the component and IHS 212 are positioned within the LGA socket 100, one or both of the frame 202 and load plate 208 may be rotated to at least partially overlap with, and apply pressure to, the IHS 212. The load lever 210 may then be rotated so that it locks with the frame 202. By rotating the load lever 210 down, the load plate 208 may be secured in a locked position such that it is applying force to the IHS 212, which in turn applies force against the component and holds the component securely within the LGA socket 100. In this embodiment, the IHS 212 may be configured such that it distributes both heat and pressure to and from the component. Therefore, the IHS 212 may help eliminate localized heat or pressure points against the component which may damage the component.

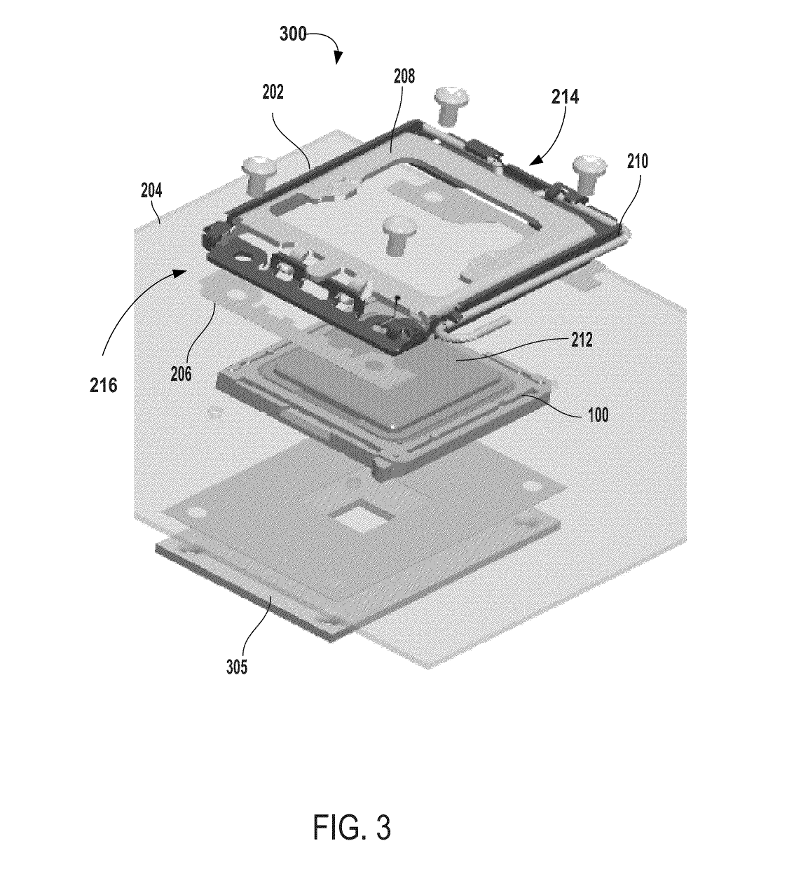

FIG. 3 depicts an exploded view 300 of an assembly such as the assembly 200 shown in FIG. 2. Specifically, FIG. 3 depicts the IHS 212 coupled with the LGA socket 100. The frame 202 with the load lever 210 and load plate 208 may then be positioned at least partially over the LGA socket 100 and the IHS 212. In addition, the assembly 200 may further comprise a backplate 305 that is on the opposite side of the PCB 204. The backplate 305 may distribute pressure or thermal energy evenly across the PCB 204 and the assembly 200 so that there are no localized pressure or heat sources that could damage one or both of the PCB 204 or an element of the assembly 200 such as the LGA socket 100.

Because the assembly 200 may include a load plate 208, a frame 202, and a load lever 210, the assembly 200 may necessarily require a relatively large footprint on the PCB 204. In some embodiments the footprint of the assembly 200 may be as large as 4,056 square millimeters (mm²). A footprint of that size may be acceptable in devices such as personal computers (PCs), set-top boxes, or other stationary items. However, there is a constant desire to decrease the size of mobile devices. One way to decrease the size of a mobile device is to decrease the size of components or assemblies of the mobile device. Therefore, an assembly 200 with a footprint of up to 4,000 mm² may in some cases be undesirable.

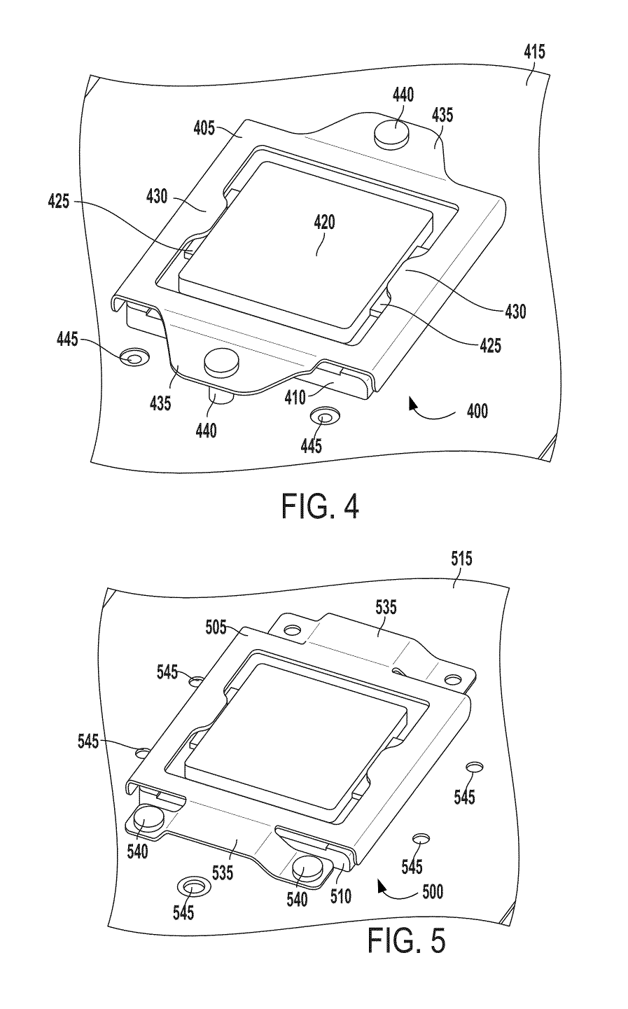

FIG. 4 depicts one embodiment of an assembly 400 comprising a mobile ILM 405 that may be used to mount a component (not shown) to an LGA socket 410 coupled with a PCB 415, for example a PCB 415 of a mobile device. In some embodiments, a thermal backing (not shown) may be disposed between the LGA socket 410 and the PCB 415. The assembly 400 may further comprise an IHS 420 with one or more protrusions 425. As described above, the IHS 420 may be coupled with a component (not shown), for example a CPU or a semiconductor die, either directly or with a thermal element disposed therebetween. The component (not shown) may be positioned such that it directly couples with the LGA socket 410. Then, the mobile ILM 405 may be placed such that one or more protrusions 430 of the mobile ILM 405 at least partially overlap the protrusions 425 of the IHS 420. The mobile ILM 405 may also have one or more tabs 435 that extend from the mobile ILM 405. The tabs 435 may be configured to receive one or more fasteners 440 that extend through the tabs 435 and into a hole in the PCB 415, for example holes 445. In some embodiments the fasteners 440 may be threaded, and configured to mate with threads in the holes 445. In other embodiments the fasteners 440 may couple with one or more fastener ends on the opposite side of the PCB 415 from the assembly 400, for example a nut or some other type of element configured to receive the fastener 440.

By coupling the mobile ILM 405 with the PCB 415 via the one or more fasteners 440, the mobile ILM 405 may be tightened to the PCB 415. As the mobile ILM 405 gets tightened to the PCB 415, the protrusions 430 of the mobile ILM 405 may in turn apply force to the protrusions 425 of the IHS 420. This force may in turn cause the IHS 420 to apply force to the component (not shown), thereby compressing the component against the LGA socket 410. In this manner, the force required by the LGA socket 410 may be achieved by using the mobile ILM 405 without requiring a footprint on the order of the assembly 200 described above with respect to FIG. 2.

FIG. 5 depicts an alternative embodiment of an assembly 500 utilizing an LGA socket 510 and a mobile ILM 505. In this alternative embodiment, the tabs 535 of the mobile ILM 505 are configured such that they may receive two fasteners 540 each. In addition, the tabs 535 are sloped at least partially downwards from the mobile ILM 505 toward the PCB 515. In this embodiment, the PCB 515 may comprise holes 545 in the PCB 515 on multiple sides of the assembly 500, such that the mobile ILM 505 may be coupled with the PCB 515 either as shown, or rotated 90 or 180 degrees in either direction. This embodiment may therefore provide the advantage of allowing the mobile ILM 505 to be coupled with the PCB 515 in a plurality of positions, thereby reducing assembly time or cost.

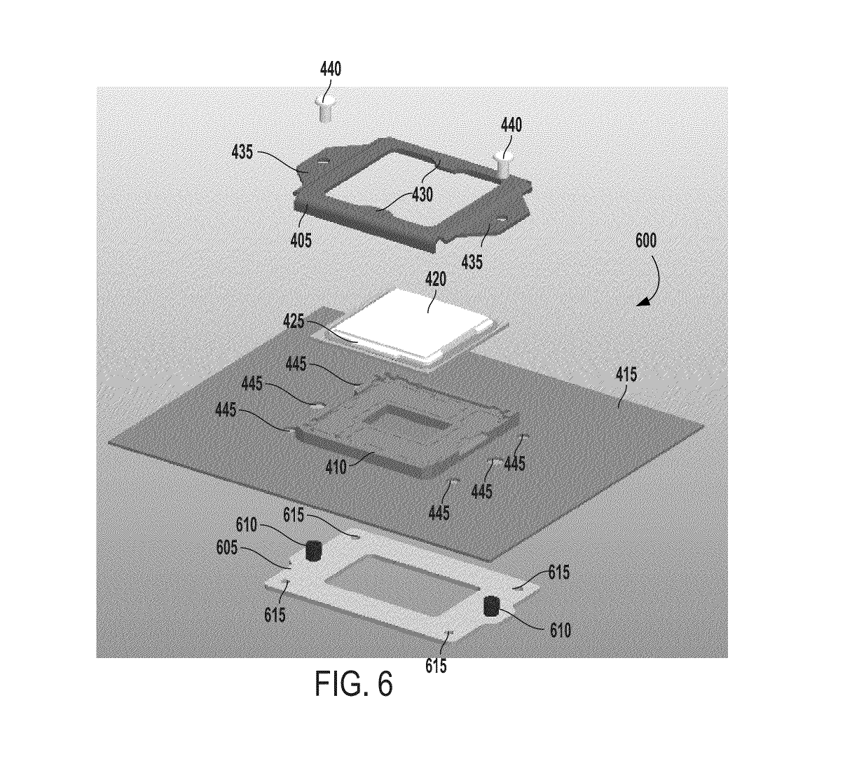

FIG. 6 depicts an exploded view 600 of an assembly such as assembly 400 depicted in FIG. 4. As described above, IHS 420 may be configured to couple with LGA socket 410. Mobile ILM 405 may then be configured to at least partially overlap the IHS 420 such that the protrusions 430 of the mobile ILM 405 at least partially overlap the protrusions 425 of the IHS 420. Fasteners 440 may be configured to go through holes in the tabs 435 of the mobile ILM 405, and then couple with one or more holes 445 of the PCB 415. In some embodiments a backplate 605 may be positioned on the opposite side of the PCB 415 from the LGA socket 410. The backplate 605 may include one or more fastener ends 610 that are configured to mate with the fasteners 440 of the assembly. For example, the fastener ends 610 may be nuts, hex nuts, or some other type of fastener end. In some embodiments the fastener ends 610 may be pliable such that they provide a buffer between the backplate 605 and the PCB 415. In some embodiments the backplate 605 may comprise a number of holes 615. The holes 615 may be threaded and configured to mate with one or more of the fasteners 440, or they may be non-threaded. The backplate 605 may serve to distribute heat and/or pressure such that there are fewer or no localized heat or pressure points against the LGA socket 410 or the PCB 415.

The mobile ILM 405 or 505, or the assemblies 400 or 500 as shown in FIGS. 4-6 are merely example embodiments. In other embodiments, the mobile ILM 405 or 505 or the IHS 420 may include more or less protrusions 430 or 425. Alternatively, the protrusions 430 or 425 may be configured differently or have a different shape. For example, mobile ILM 405 may have a plurality of protrusions 430 on each side of the mobile ILM 405, or protrusions 430 on all four sides of the mobile ILM 405. Similarly, IHS 420 may have multiple protrusions 425 on each side of the IHS 420, or protrusions 425 on more sides of the IHS 420 than are shown. Additionally, the protrusions 425 or 430 or tabs 435 or 535 may be other shapes in other embodiments, and the particular shapes shown in FIG. 3 or FIG. 4 are not limiting. Finally, fasteners 440 or 540 may be any suitable fastener, for example a screw, a bolt, or some other type of fastener. In some embodiments fasteners 440 or 540 may be threaded while in other embodiments fasteners 440 or 540 may be non-threaded.

In some embodiments, an assembly such as assemblies 400 or 500 may be coupled with a thermal mounting (not shown). The thermal mounting may have a first side that is configured to couple with the mobile ILM 405 or 505, and/or the IHS 420. The thermal mounting may further include a second side opposite the first side. The second side of the thermal mounting may be configured to couple with one or more thermal components. For example, the second side of the thermal mounting may be recessed such that it can receive at least one of the thermal components. In other embodiments, the thermal mounting may be configured to at least partially or wholly surround one or more of the thermal components. In this way, the thermal components may be used to transfer heat to or from the thermal mounting, and through the thermal mounting to or from the assemblies 400 or 500, the ILMs 405, or 505, and/or the IHS 420. In some embodiments, the thermal mounting may be configured to couple with the PCB 415 or 515 via holes 445 or 545. In other embodiments the thermal mounting may couple with the ILM 535, for example by using the same fasteners 540 to couple the thermal mounting, the ILM 505 and the PCB 515 to one another via holes 545.

The above described assemblies 400 or 500 may provide significant benefits over assemblies utilizing LGA sockets such as assembly 200. For example, an assembly such as assemblies 400 or 500 may have a footprint on a PCB that is on the same order of PGA sockets, and less than half of the assembly 200 described above. In some embodiments the assemblies 400 or 500 may only have a footprint of less than 2000 mm². Additionally, the assemblies 400 or 500 may be up to several millimeters closer to other components such as memory, for example 3.25 mm closer to the component, while the assembly 200 may require the components to be placed up to 2.5 mm further from the assembly 200. An assembly utilizing a thermal mounting may also have a footprint that is similar to the footprint of an assembly utilizing a PGA socket, which in some embodiments may be 51.5 mm×32.5 mm. By contrast, assembly 200 may have a significantly larger footprint of up to 52 mm×78 mm when coupled with a thermal mounting. The specific values given above are merely examples, and other embodiments may have alternative values that provide the same or similar advantages.

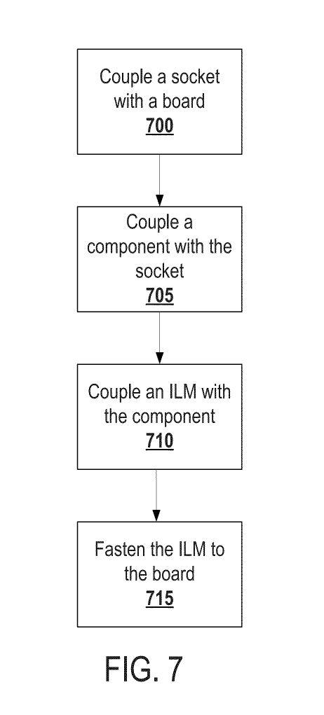

FIG. 7 illustrates a flowchart for constructing and using an assembly such as assemblies 400 or 500. Description of specific elements will be given with reference to assembly 400 as shown in FIG. 4, though it will be understood that similar elements such as those shown with respect to assembly 500 in FIG. 5 may be used instead.

First, a socket such as LGA socket 410 may be coupled with PCB 415 at 700. As noted above, the LGA socket 410 may be coupled with the PCB 415 via solder, glue, or some other form of connection. Next, a component such as a component coupled with IHS 420 may be coupled with the LGA socket 410 at 705. As described above, the component may be a CPU, a semiconductor die, or some other component of an electrical circuit or chipset. Specifically, the component may comprise a first side and a second side wherein the first side is opposite the IHS 420 and includes electrical contacts configured to couple with the contacts 104 of the LGA socket 410.

An ILM such as ILM 405 may then be placed over the component and the IHS 420 at 710. Specifically, the ILM 405 may couple with the second side of the component, which may generally be understood to be opposite the first side. The IHS 420 may be disposed in between the component and the ILM 405. As described the above, the ILM 405 may at least partially overlap the component and the IHS 420 such that the ILM 405 applies pressure to the IHS 420 and/or the component.

Finally, the ILM 405 may be fastened to the PCB 415 via one or more of the fasteners 440 at 715. In this way, the pressure that the ILM 405 is exerting on the IHS 420 may be increased. Additionally, the ILM 405 may be secured over the IHS 420 such that the IHS 420 and the component are held securely within the LGA socket 410.

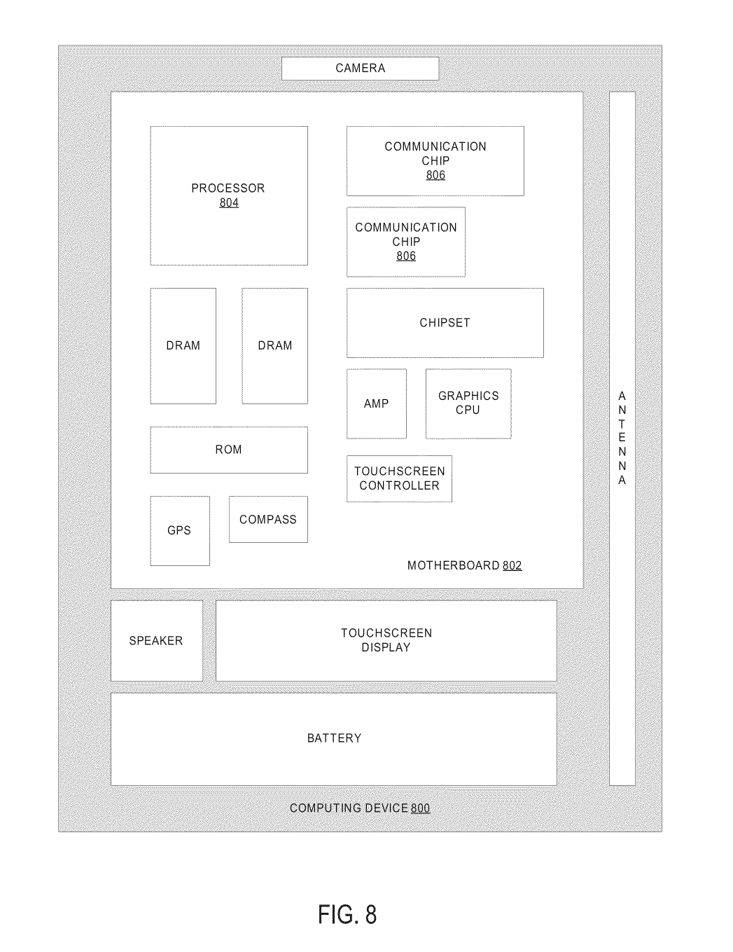

Embodiments of the present disclosure may be implemented into a system using any suitable hardware and/or software to configure as desired. FIG. 8 schematically illustrates a computing device 800 in accordance with one implementation of the invention. The computing device 800 may house a board such as motherboard 802. The motherboard 802 may include a number of components, including but not limited to a processor 804 and at least one communication chip 806. The processor 804 may be physically and electrically coupled to the motherboard 802, for example by assemblies 400 or 500. In some implementations, the at least one communication chip 806 may also be physically and electrically coupled to the motherboard 802, for example by assemblies 400 or 500. In further implementations, the communication chip 806 may be part of the processor 804.

Depending on its applications, computing device 800 may include other components that may or may not be physically and electrically coupled to the motherboard 802, for example by assemblies 400 or 500. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 806 may operate in accordance with other wireless protocols in other embodiments.

The computing device 800 may include a plurality of communication chips 806. For instance, a first communication chip 800 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 may include a semiconductor die in an IC package assembly. The term “processor” may refer to any device or portion of a device that processes electronic data from registers and/or memory to transform that electronic data into other electronic data that may be stored in registers and/or memory.

The communication chip 806 may also include a die in an IC package assembly. In further implementations, another component (e.g., memory device or other integrated circuit device) housed within the computing device 800 may contain a die in an IC package assembly.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data, for example an all-in-one device such as an all-in-one fax or printing device.

Embodiments may include methods, assemblies, and devices including an LGA socket. In one embodiment, an assembly may comprise an LGA socket configured to couple with a board of a mobile device. The LGA socket may be further configured to couple with a first side of a component of the mobile device. The embodiment may further comprise an ILM configured to overlap the component and the LGA socket on a second side of the component opposite the first side, and the mobile ILM may be further configured to couple with the board via one or more fasteners. In some embodiments, the mobile ILM may be configured to apply pressure to the second side of the component.

In embodiments, the mobile device assembly may further comprise a backplate configured to couple with the board at a location opposite from a location at which the LGA socket is configured to couple with the board. The mobile ILM may be configured to couple with the component on a first side of the mobile ILM, and the mobile ILM may be further configured to couple with a thermal mounting on a second side of the mobile ILM opposite the first side, the thermal mounting configured to receive one or more thermal components. The mobile ILM may be further configured to couple with the thermal mounting via the one or more fasteners discussed above.

In some embodiments, the component may be a CPU. In some embodiments, the one or more fasteners may be configured to pass through one or more openings in the mobile ILM and couple with the board. In some embodiments, the board may be a board of a PDA, a smartphone, a computing tablet, an e-reader, an ultrabook, or a laptop computer. In some embodiments, the mobile device assembly may occupy a lateral space of less than 2000 square millimeters (mm²). In some embodiments, the mobile ILM may be further configured to removably couple with the board via the one or more fasteners.

Other embodiments may include a mobile device comprising a board, an LGA socket coupled with the board, and a component coupled with the LGA socket such that a first side of the component is in direct contact with the LGA socket. Further, a mobile ILM may be coupled with the board via one or more fasteners wherein the component is positioned between the ILM and the LGA socket, and the mobile ILM is in direct contact with a second side of the component and applying pressure to the second side of the component.

The mobile device may further comprise a backplate coupled with the board where the backplate is positioned on a first side of the board and the LGA socket is positioned on a second side of the board opposite the first side. In some embodiments, the mobile device may further comprise thermal components coupled with a thermal mounting, wherein the thermal mounting is coupled with the mobile ILM. In some embodiments, the mobile ILM may be coupled with the thermal mounting via the one or more fasteners.

In some embodiments, the component may include a semiconductor die. In certain embodiments, the one or more fasteners are configured to pass through one or more openings in the mobile ILM and couple with the board. In embodiments, the mobile device may be a PDA, a smartphone, a computing tablet, an e-reader, an ultrabook, or a laptop computer. Further, the LGA socket, when coupled with the board, may occupy a lateral space of less than 2000 mm². Further, the mobile ILM may be removably coupled with the board via the one or more fasteners.

Other embodiments may include a method for mounting a component on a board of a mobile device. The method may comprise coupling an LGA socket with the board, coupling the LGA socket with a first side of the component, and coupling a second side of the component, which is opposite the first side, with a mobile ILM configured to overlap the component and the LGA socket and apply pressure to the second side of the component. The method may further comprise coupling the mobile ILM with the board via one or more fasteners.

The method may further comprise coupling a thermal backplate with the board. In embodiments, the mobile ILM may be configured to couple with the component on a first side of the mobile ILM, and the method may further comprise coupling the mobile ILM with one or more thermal components on a second side of the mobile ILM, the second side being opposite the first side, via a thermal mounting coupled with the second side of the mobile ILM and configured to receive the one or more thermal components.

In embodiments, the method may further comprise coupling the mobile ILM with the thermal mounting via the one or more fasteners. In embodiments, the component may include a semiconductor die. In other embodiments, the component may be a semiconductor die. In some embodiments, coupling the mobile ILM with the board via the one or more fasteners may comprise passing the one or more fasteners through one or more openings in the mobile ILM so that the one or more fasteners are in contact with the board.

In some embodiments, the mobile device may be a PDA, a smartphone, a computing tablet, an e-reader, an ultrabook, or a laptop computer. In some embodiments, the LGA socket, subsequent to coupling the mobile ILM with the board, may occupy a lateral space of less than 2000 mm² of a surface of the board. In other embodiments, coupling the mobile ILM with the board may comprise removably coupling the ILM with the board via the one or more fasteners.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

What is claimed is:

1. A mobile device assembly, comprising:
a land grid array (LGA) socket configured to couple with a board of a mobile device, the LGA socket further configured to couple with a first side of a component of the mobile device; and
a mobile independent loading mechanism (ILM) configured to overlap the component and the LGA socket on a second side of the component opposite the first side, the mobile ILM further configured to couple with the board via one or more fasteners;
wherein the mobile ILM is configured to apply pressure to the second side of the component.

2. The mobile device assembly of claim 1, further comprising a backplate configured to couple with the board at a location opposite from a location at which the LGA socket is configured to couple with the board.

3. The mobile device assembly of claim 1, wherein the mobile ILM is configured to couple with the component on a first side of the mobile ILM, and the mobile ILM is further configured to couple with a thermal mounting on a second side of the mobile ILM opposite the first side, the thermal mounting configured to receive one or more thermal components.

4. The mobile device assembly of claim 3, wherein the mobile ILM is configured to couple with the thermal mounting via the one or more fasteners.

5. The mobile device assembly of claim 1, wherein the component comprises a central processing unit (CPU).

6. The mobile device assembly of claim 1, wherein the one or more fasteners are configured to pass through one or more openings in the mobile ILM and couple with the board.

7. The mobile device assembly of claim 1, wherein the board is a board of a personal digital assistant (PDA), a smartphone, a computing tablet, an e-reader, an ultrabook, or a laptop computer.

8. The mobile device assembly of claim 1, wherein the mobile device assembly occupies a lateral space of less than 2000 square millimeters (mm²).

9. The mobile device assembly of claim 1, wherein the mobile ILM is further configured to removably couple with the board via the one or more fasteners.

10. A mobile device comprising:
a board;
a land grid array (LGA) socket coupled with the board;
a component coupled with the LGA socket such that a first side of the component is in direct contact with the LGA socket; and
a mobile independent loading mechanism (ILM) coupled with the board via one or more fasteners wherein the component is positioned between the ILM and the LGA socket, and the mobile ILM is in direct contact with a second side of the component and applying pressure to the second side of the component.

11. The mobile device of claim 10, further comprising a backplate coupled with the board where the backplate is positioned on a first side of the board and the LGA socket is positioned on a second side of the board opposite the first side.

12. The mobile device of claim 10, wherein the mobile device further comprises thermal components coupled with a thermal mounting, wherein the thermal mounting is coupled with the mobile ILM.

13. The mobile device of claim 12, wherein the mobile ILM is coupled with the thermal mounting via the one or more fasteners.

14. The mobile device of claim 10, wherein the component includes a semiconductor die.

15. The mobile device of claim 10, wherein the one or more fasteners are configured to pass through one or more openings in the mobile ILM and couple with the board.

16. The mobile device of claim 10, wherein the mobile device is a personal digital assistant (PDA), a smartphone, a computing tablet, an e-reader, an ultrabook, or a laptop computer.

17. The mobile device of claim 10, wherein the LGA socket, when coupled with the board, occupies a lateral space of less than 2000 square millimeters (mm²).

18. The mobile device of claim 10, wherein the mobile ILM is removably coupled with the board via the one or more fasteners.

19. A method for mounting a component on a board of a mobile device, comprising:
coupling a land grid array (LGA) socket with the board;
coupling the LGA socket with a first side of the component;
coupling a second side of the component opposite the first side with a mobile independent loading mechanism (ILM) configured to overlap the component and the LGA socket and apply pressure to the second side of the component; and
coupling the mobile ILM with the board via one or more fasteners.

20. The method of claim 19, further comprising coupling a thermal backplate with the board.

21. The method of claim 19, wherein the mobile ILM is configured to couple with the component on a first side of the mobile ILM, and further comprising coupling the mobile ILM with one or more thermal components on a second side of the mobile ILM opposite the first side via a thermal mounting coupled with the second side of the mobile ILM and configured to receive the one or more thermal components.

22. The method of claim 21, further comprising coupling the mobile ILM with the thermal mounting via the one or more fasteners.

23. The method of claim 19, wherein the component includes a semiconductor die or is a semiconductor die.

24. The method of claim 19, wherein coupling the mobile ILM with the board via the one or more fasteners comprises passing the one or more fasteners through one or more openings in the mobile ILM so that the one or more fasteners are in contact with the board.

25. The method of claim 19, wherein the mobile device is a personal digital assistant (PDA), a smartphone, a computing tablet, an e-reader, an ultrabook, or a laptop computer.

26. The method of claim 19, wherein the LGA socket, subsequent to coupling the mobile ILM with the board, occupies a lateral space of less than 2000 square millimeters (mm²) of a surface of the board.

27. The method of claim 19, wherein coupling the mobile ILM with the board comprises removably coupling the ILM with the board via the one or more fasteners.
